(19) United States
(12) Patent Application Publication
(10) Pub. No.: US 2025/0283221 A1
(43) Pub. Date: Sep. 11, 2025

(54) CARRIER RING WITH TABS

(71) Applicant: Lam Research Corporation, Fremont, CA (US)

(72) Inventors: Yanhui Huang, Sherwood, OR (US); Fayaz A. Shaikh, Lake Oswego, OR (US); Nick Ray Linebarger, Jr., Tualatin, OR (US); Katsunori Yoshizawa, Tigard, OR (US)

(21) Appl. No.: 18/863,615

(22) PCT Filed: May 10, 2023
(86) PCT No.: PCT/US2023/021778

§ 371 Date: Nov. 6, 2024

Related U.S. Application Data
(60) Provisional application No. 63/364,691, filed on May 13, 2022.

(51) Int. Cl. C23C 16/458; H01L 21/02; H01L 21/3205

(52) U.S. Cl. CPC C23C 16/4585; H01L 21/02164; H01L 21/0217; H01L 21/32055

(57) ABSTRACT

A carrier ring with tabs for use with a semiconductor processing apparatus is provided. The carrier ring may include a ring having an outer portion and an inner portion and defining a plane. The carrier ring may include tabs about an inner perimeter of the inner portion. The ring and the tabs may have physical characteristics configured to enable more backside deposition of the semiconductor substrate at a plurality of locations of the semiconductor substrate corresponding to the tabs, as compared to a ring without the physical characteristics. Such characteristics of the ring and tabs may include an inner diameter of the ring, inner diameter of the tabs, quantity of the tabs, width of the tabs, an angle of the tab with respect to the plane. These characteristics may reduce a substrate contact area and increase deposition areas near substrate edges, which may increase the evenness of film thicknesses.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Semiconductor device fabrication often involves deposition of a stack of layers on a wafer substrate. Deposition and other processing to form the devices often occur on one side of the substrate, often referred to as the front face of the substrate. As the deposited layers build up, they can introduce stress in the substrate. A large net compressive or tensile stress can cause the substrate to bow, in which a deviation occurs from a plane of a substrate (e.g., an average midplane of a semiconductor substrate), which is undesirable. Such substrates can be highly sensitive to such deviations. Depositing a film on the backside of the substrate can counteract the bowing and increase deposition areas on the same substrate.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

In one aspect of the present disclosure, a carrier ring is disclosed. In some embodiments, the carrier ring is configured to support a semiconductor substrate, and the carrier ring includes: a ring having an outer portion and an inner portion and defining a plane, the inner portion having an inner perimeter having a first diameter of about 298.4 to 299.5 millimeters (mm); and a plurality of inwardly extending tabs disposed about the inner perimeter of the inner portion of the ring, the plurality of inwardly extending tabs having inner edges defining a circle having a second diameter of about 296.0 to 298.5 mm.

In some variants, the first diameter of the inner portion of the ring is about 299.0 mm; and the second diameter of the plurality of inwardly extending tabs is about 297.0 mm.

In some variants, the plurality of inwardly extending tabs comprise at least 8 inwardly extending tabs.

In some variants, at least one of the plurality of inwardly extending tabs has a width of about 0.5 to 1.5 mm.

In some variants, the width of the at least one of the plurality of inwardly extending tabs is about 1.0 mm.

In some variants, at least one of the plurality of inwardly extending tabs comprises at least a portion of a top surface having an angle that is neither parallel to nor perpendicular to the plane.

In some variants, the angle of the portion of the top surface is between about 5 to 20 degrees with respect to the plane.

In some variants, the top surface of the at least one of the plurality of inwardly extending tabs comprises a minimum contact area (MCA) configured to make physical contact with the semiconductor substrate.

In some variants, the outer portion is about 0.3 to 0.7 mm thick, and the inner portion is about 0.1 to 0.5 mm thick.

In some variants, at least a portion of the plurality of inwardly extending tabs disposed about the inner perimeter of the inner portion of the ring are configured to form one or more conductive grounding points on the semiconductor substrate.

In some embodiments, the carrier ring is configured to support a semiconductor substrate, and the carrier ring includes: a ring comprising an inner portion configured to support the semiconductor substrate during backside deposition on the semiconductor substrate, the ring defining a plane; and 8 to 15 inwardly extending tabs disposed about the inner portion of the ring, and configured to contact the semiconductor substrate during the backside deposition on the semiconductor substrate; wherein at least one of the 8 to 15 inwardly extending tabs has a width of about 0.5 to 1.5 mm.

In some variants, the at least one of the 8 to 15 inwardly extending tabs comprises a top surface of having an angle of about 15 degrees or less with respect to the plane.

In some variants, the 8 to 15 inwardly extending tabs have inner edges defining a first diameter of about 296.0 to 298.5 mm; and the 8 to 15 inwardly extending tabs have outer edges attaching to the ring and defining a second diameter of about 298.4 to 299.5 mm.

In some variants, at least a portion of the 8 to 15 inwardly extending tabs are configured to allow formation of one or more conductive grounding points on the semiconductor substrate.

In another aspect of the present disclosure, a method of depositing one or more layers on a backside of a semiconductor substrate is disclosed. In some embodiments, the method includes: (a) supporting the semiconductor substrate on a carrier ring, the carrier ring comprising: a ring having an outer portion and an inner portion and defining a plane, the inner portion having an inner perimeter having a first diameter of about 298.4 to 299.5 millimeters (mm); and a plurality of inwardly extending tabs disposed about the inner perimeter of the inner portion of the ring, the plurality of inwardly extending tabs having inner edges defining a circle having a second diameter of about 296.0 to 298.5 mm; and (b) exposing the backside of the semiconductor substrate to process conditions that cause the one or more layers to deposit on the backside of the semiconductor substrate.

In some variants, the process conditions that cause the one or more layers to deposit comprise exposure to a chemical precursor of at least one of the one or more layers.

In some variants, at least one of the one or more layers on the backside of the semiconductor substrate comprises polysilicon, a silicon oxide, a silicon nitride, or any combination thereof.

In some variants, the first diameter of the inner portion of the ring is about 299.0 mm; and the second diameter of the plurality of inwardly extending tabs is about 297.0 mm.

In some variants, the plurality of inwardly extending tabs comprise at least 8 inwardly extending tabs, at least one of the at least 8 inwardly extending tabs having a width of about 0.5 to 1.5 mm.

In some variants, at least one of the plurality of inwardly extending tabs comprises at least a portion of a top surface having an angle that is neither parallel to nor perpendicular to the plane, and the angle is about 5-20 degrees with respect to the plane.

These and other features of the disclosed embodiments will be described in detail below with reference to the associated drawings.

### BRIEF DESCRIPTION OF DRAWINGS

FIGS. 1A and 1B are block diagrams that illustrate substrate processing systems used to perform processing on a substrate, according to some embodiments.

FIG. 2A is a simplified diagram of a carrier ring and locations of tabs, according to some embodiments.

FIG. 2B is a graph of thickness of the film with respect to example angular positions of the carrier ring of FIG. 2A.

FIG. 3A is a diagram illustrating a semiconductor substrate and various concentric radial points.

FIG. 3B is a map illustrating a map of example radial data points.

FIG. 3C is a table indicating example average thicknesses of deposited film at various radii.

FIG. 3D is a graph illustrating differences between the example maximum average film thickness and example film thicknesses along angular positions of a circle defined by a given radius.

FIG. 3E shows a graph that indicates example level differences along angular positions, determined by subtracting example given film thicknesses by the example maximum average film thickness.

FIG. 4 is a graph that illustrates example changes in thickness differences with respect to the radius of a substrate placed on a carrier.

FIG. 5A is a simplified diagram that illustrates components of a substrate processing system, according to some embodiments.

FIGS. 5B and 5C are close-up diagrams of cross-sectional portion of the carrier ring of FIG. 5A, according to some embodiments.

FIG. 6A is a perspective view of a carrier ring, according to some embodiments.

FIG. 6B is a top-down view of the carrier ring of FIG. 6A, according to some embodiments.

FIG. 6C is a top-down, close-up view of a tab of the carrier ring of FIG. 6A, according to some embodiments.

FIG. 6D is a perspective view of the tab of FIG. 6C, according to some embodiments.

FIG. 6E is a cross-sectional view of the tab and the carrier ring across a cross-section of FIG. 6C, according to some embodiments.

FIG. 6F is a cross-sectional view of a non-tab position and the carrier ring across another cross-section of FIG. 6C, according to some embodiments.

FIG. 7 is a diagram illustrating one example embodiment possessing various optimizations associated with at least one tab of a carrier ring.

FIG. 8 depicts comparisons between existing carrier rings and tabs, and an example carrier ring and tab disclosed herein, at tab positions and non-tab positions, according to some embodiments.

FIG. 9 is a diagram of a semiconductor wafer positioned on a carrier ring having a plurality of tabs, according to some embodiments.

FIG. 10 is a diagram of a processed substrate from that may be clamped onto a pedestal chuck, according to some embodiments.

FIG. 11 is a flow diagram illustrating a method for obtaining an apparatus configured to support a semiconductor substrate, according to some embodiments.

FIG. 12 is a flow diagram illustrating a method of depositing one or more layers on a backside of a semiconductor substrate, according to some embodiments.

### DETAILED DESCRIPTION

This disclosure relates to carrier rings used for semiconductor processing.

Dimensions of features (e.g., lines, traces, circuits) fabricated on a wafer substrate may become easily distorted based on slight positioning or bowing deviations of the substrate, as features (which can reach the nanometer scale) can require precise processing. Moreover, such substrates are typically thin and susceptible to internal stress or tensile/compressive stress, especially during fabricating processes (deposition, etching, heating, layering, etc.). Further, certain processing steps (e.g., photolithography) are very precise and can produce poor results if the substrate is not substantially flat. The problem may be manifest as lithography defocus. Bowing is especially likely to occur where large stacks of materials are deposited, for example, in the context of 3D NAND (three-dimensional not-AND) devices, a type of non-volatile flash memory in which memory cells are stacked in multiple layers. Where bowing is significant, it can deleteriously affect subsequent processing steps. For instance, the substrate may fail to chuck correctly if the bowing is too great.

One example stack that may cause these problems is a stack having alternating layers of oxide and nitride (e.g., silicon oxide, silicon nitride, silicon oxide, silicon nitride). Another example stack likely to cause bowing includes alternating layers of oxide and polysilicon (e.g., silicon oxide, polysilicon, silicon oxide, polysilicon). Other examples of stack materials that may be problematic include, but are not limited to, tungsten and titanium nitride. The materials in the stacks may be deposited through chemical vapor deposition techniques such as plasma enhanced chemical vapor deposition (PECVD), low pressure chemical vapor deposition (LPCVD), metal organic chemical vapor deposition (MOCVD), atomic layer deposition (ALD), plasma enhanced atomic layer deposition (PEALD), or through direct metal deposition (DMD), etc. These examples are not intended to be limiting.

Some techniques devised for combatting bowing involve tuning deposition processes to reduce or counteract internal stresses in deposited layers. For example, some processes involve depositing a film on the backside of the substrate, such as deposition of a high stress dielectric film using chemical vapor deposition (CVD) on the backside of the substrate. If the backside film has an internal stress that is of the same type (tensile or compressive) and of comparable magnitude to that of the internal stress created on the frontside, the backside film effectively counteracts and corrects the bow. As a result, the substrate may have a more neutral bow, which means that it becomes flatter with less bowing.

The material deposited on the backside of the substrate may be a dielectric material in various embodiments. In some cases, an oxide and/or nitride (e.g., silicon oxide/silicon nitride) may be used. Examples of silicon-containing reactants that may be used include, but are not limited to, silanes, halosilanes, and aminosilanes. A silane contains hydrogen and/or carbon groups, but does not contain a halogen. Examples of silanes are silane (SiH4), disilane (Si2H6), and organo silanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like. A halosilane contains at least one halogen group and may or may not contain hydrogens and/or carbon groups. Examples of halosilanes are iodosilanes, bromosilanes, chlorosilanes and fluorosilanes. Although halosilanes, particularly fluorosilanes, may form reactive halide species that can etch silicon materials, in certain embodiments described herein, the silicon-containing reactant is not present when a plasma is struck. Specific chlorosilanes are tetrachlorosilane (SiCl4), trichlorosilane (HSiC13), dichlorosilane (H2SiC12), monochlorosilane (ClSiH3), chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like. An aminosilane includes at least one nitrogen atom bonded to a silicon atom, but may also contain hydrogens, oxygens, halogens and carbons. Examples of aminosilanes are mono-, di-, tri- and tetra-aminosilane (H3Si(NH2)4, H2Si(NH2)2, HSi(NH2)3 and Si(NH2)4, respectively), as well as substituted mono-, di-, tri- and tetra-aminosilanes, for example, t-butylaminosilane, methylaminosilane, tert-butylsilanamine, bis(tertiarybutylamino)silane (SiH2(NHC(CH3)3)2 (BTBAS), tert-butyl silylcarbamate, SiH(CH3)—(N(CH3)2)2, SiHCl—(N(CH3)2)2, (Si(CH3)2NH)3 and the like. A further example of an aminosilane is trisilylamine (N(SiH3)). Other potential silicon-containing reactants include tetraethyl orthosilicate (TEOS), and cyclic and non-cyclic TEOS variants such as tetramethoxysilane (TMOS), fluorotriethoxysilane (FTES), Trimethylsilane (TMS), octamethyltetracyclosiloxane (OMCTS), tetramethylcyclotetrasiloxane (TMCTSO), dimethyldimethoxysilane (DMDS), hexamethyldisilazane (HMDS), hexamethyldisiloxane (HMDSO), hexamethylcyclotrisiloxane (HMCTSO), dimethyldiethoxysilane (DMDEOS), methyltrimethoxysilane (MTMOS), tetramethyldisiloxane (TMDSO), divinyltetramethyldisiloxane (VSI2), methyltriethoxysilane (MTEOS), dimethyltetramethoxydisiloxane (DMTMODSO), ethyltriethoxysilane (ETEOS), ethyltrimethoxysilane (ETMOS), hexamethoxydisilane (HMODS), bis (triehtoxysilyl) ethane (BTEOSE), bis(trimethoxysilyl)ethane (BTMOSE), dimethylethoxysilane (DMEOS), tetraethoxydimethyldisiloxane (TEODMDSO), tetrakis(trimehtylsiloxy)silane (TTMSOS), tetramethyldiethoxydisiloxane (TMDEODSO), triethoxysilane (TIEOS), trimethoxysilane (TIMEOS), or tetrapropoxysilane (TPOS).

Example nitrogen-containing reactants include, but are not limited to, ammonia, hydrazine, amines (e.g., amines hearing carbon) such as methylamine, dimethylamine, ethylamine, isopropylamine, t-butylamine, di-t-butylamine, cyclopropylamine, sec-butylamine, cyclobutylamine, isoamylamine, 2-methylbutan-2-amine, trimethylamine, diisopropylamine, diethylisopropylamine, di-t-butylhydrazine, as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants.

Examples of oxygen-containing co-reactants include oxygen, ozone, nitrous oxide, carbon monoxide, nitric oxide, nitrogen dioxide, sulfur oxide, sulfur dioxide, oxygen-containing hydrocarbons (CxHyOz), water, mixtures thereof, etc.

In recent semiconductor processing equipment, the substrate may rest on a pedestal during semiconductor processing operations. The pedestal may be a so-called shower-pedestal, which is a pedestal-like structure that has a large number of gas distribution ports distributed across its upper surface (much like a showerhead has a number of gas distribution ports distributed across its underside). The gas distribution ports may be fluidically connected with one or more plenums located within the shower-pedestal. The one or more plenums may, in turn, be fluidically connected with one or more processing gas sources that may be controllable so as to allow processing gases to be flowed out of the shower-pedestal via those gas distribution ports.

Such semiconductor processing tools may also have one or more carrier ring supports that may be configured to support a carrier ring that may, in turn, support the substrate during processing operations. The one or more carrier ring supports may be designed to allow the carrier ring and any substrate supported thereby to be held at an elevated location above the shower-pedestal, such that there is a gap in between the shower-pedestal and the substrate to which processing gas is able to be delivered. Such semiconductor processing tools thus allow the underside of the substrate to be subjected to substrate processing operations instead of the top side of the substrate, allowing deposition of a film on the backside of the substrate.

However, carrier rings may include tabs that obstruct backside film deposition on the areas of the substrate that overlap with the tabs. Maximizing or optimizing the available space for deposition is desired to allow fabrication of additional or larger components. Even an increase of a few square millimeters (mm) on the backside of a 200-, 300-, or 450-mm substrate can improve space efficiency for fabrication.

Thus, a carrier ring with physical features that balance the size, shape, quantity, and other parameters associated with the tabs of the carrier ring is desired.

The following terms are used throughout the present specification:

“Wafer bow” as used herein may refer to a deformation of a substrate or a wafer. Wafer bow may occur during fabrication, for example, as a result of stress to the substrate during deposition of materials on an active surface of the substrate. Wafer bow may occur during various types of fabrication, such as when large stacks of materials are deposited. Wafer bow may cause complications in subsequent processing steps. For example, the substrate may fail to chuck correctly if an amount of bowing is too large. Moreover, some processing steps (e.g., photolithography) may produce poor results if performed on a substrate that is excessively bowed.

Wafer bow may be measured as a deviation of the mean or median distance of the surface of the substrate to a reference plane. The point of the median surface of the substrate may be the center point (e.g., in the case of concave or domed bowing), or an edge point of the substrate and/or an average edge point of the substrate (e.g., in the case of warping or convex bowing).

A “platen” as used herein refers to a top surface of an electrostatic chuck (ESC) on which a substrate or wafer undergoing fabrication is positioned. There may be a gap between the substrate and the platen surface (e.g., the upper surface), which is generally referred to herein as “d.”

A “pedestal” as used herein may refer to a structure or housing that supports, or includes, the platen.

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, or 300 mm, or 450 mm. Besides semiconductor wafers, other work pieces that may take advantage of the disclosed embodiments include various articles such as printed circuit boards, magnetic recording media, magnetic recording sensors, mirrors, optical elements, display devices or components such as backplanes for pixelated display devices, flat-panel displays, micro-mechanical devices and the like. The work piece may be of various shapes, sizes, and materials.

A “semiconductor device fabrication operation” as used herein is an operation performed during fabrication of semiconductor devices. As referred to herein, such a fabrication operation is sometimes simply referred to as a “process” or as “processing.” Examples of processing include deposition of a material on a substrate, selectively etching material from a substrate, and ashing of photoresist on a substrate. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

“Manufacturing equipment” refers to equipment in which a manufacturing process takes place. Manufacturing equipment often has a process chamber in which the workpiece resides during processing. Typically, when in use, manufacturing equipment performs one or more semiconductor device fabrication operations. Examples of manufacturing equipment for semiconductor device fabrication include deposition reactors such as electroplating cells, physical vapor deposition reactors, chemical vapor deposition reactors, and atomic layer deposition reactors, and subtractive process reactors such as dry etch reactors (e.g., chemical and/or physical etch reactors), wet etch reactors, and ashers.

As referred to herein, manufacturing equipment is sometimes simply referred to as a “process chamber.” In various embodiments, a process chamber is typically a sealed enclosure in which a substrate is immobilized during processing. The process chamber may include components associated with delivery of and removal of gases. It may also include components associated with generating a plasma and controlling properties of the plasma within the chamber. It may include components for controlling the pressure, including pulling a vacuum within the chamber. In the context of this disclosure, the process chamber may include a pedestal on which the substrate sits while it is being processed. A pedestal may be outfitted with a chuck such as an ESC to hold the substrate in position during processing.

### Substrate Processing System

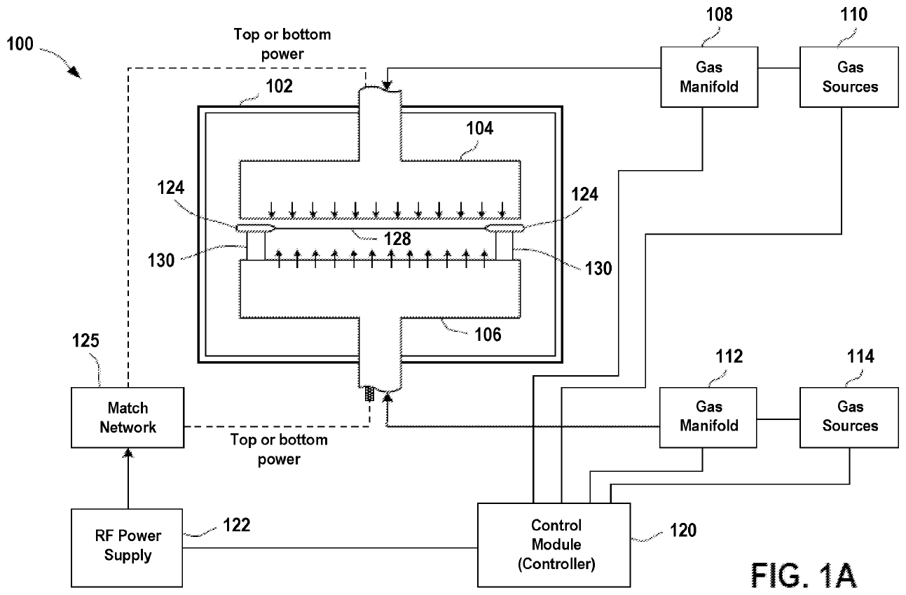

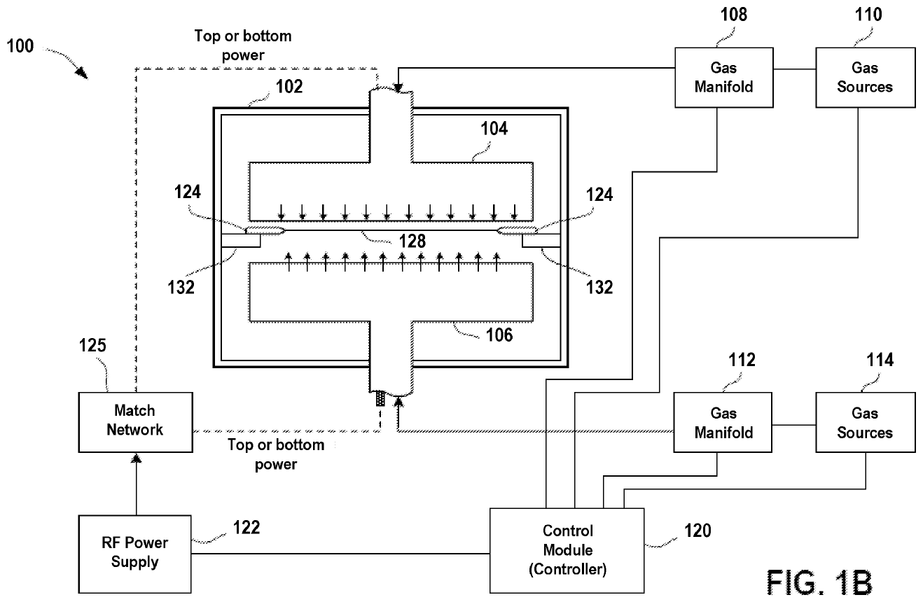

FIG. 1A is a block diagram that illustrates a substrate processing system 100 used to perform processing on a substrate 128 (also referred to as a wafer), according to some embodiments. As shown, the substrate processing system may include a chamber 102. A center column may be configured to support a pedestal for when a top surface of the substrate 128 is being processed, e.g., a film is being formed on the top surface of the substrate 128, or on the backside of the substrate 128. The pedestal, in accordance with some embodiments disclosed herein, may be referred to as a showerhead-pedestal (“show-ped”) 106. A showerhead 104 may be disposed over the show-ped 106.

In some embodiments, the showerhead 104 may be electrically coupled to power supply 122 via a match network 125. The power supply 122 may be controlled by a control module 120, e.g., a controller. In some embodiments, power may be provided to the show-ped 106 instead of the showerhead 104. The control module 120 may be configured to operate the substrate processing system 100 by executing process input and control for specific process recipes. Depending on whether the top surface of the substrate 128 is receiving a deposited film or the bottom surface of the substrate 128 is receiving a deposited film, the controller module 120 may set various operational inputs for a process recipe, such as power levels, timing parameters, process gasses, mechanical movement of the substrate 128, and/or the height of the substrate 128 relative to the show-ped 106.

In some embodiments, the center column may also include lift pins, which are controlled by a lift pin control. Such lift pins may be used to raise the substrate 128 from the show-ped 106 to allow an end effector (not shown) to pick the substrate 128 and to lower the substrate 128 after being placed by the end effector. The end effector may also place the substrate 128 over spacers 130. As will be described below, the spacers 130 may be sized to provide a controlled separation of the substrate 128 between a top surface of the showerhead 104 (facing the substrate 128) and a top surface of the show-ped 106 (facing the substrate 128).

In some embodiments, the substrate processing system 100 may further include a first gas manifold 108 that is connected to first gas sources 110, e.g., gas chemistry supplies from a facility and/or inert gases. Depending on the processing being performed over a top surface of the substrate 128, the control module 120 may controls the delivery of first gas sources 110 via the first gas manifold 108. The chosen gases may then be flown into the showerhead 104 and distributed in a space volume defined between a face of the showerhead 104 that faces that substrate 128 when the substrate 128 is resting over the pedestal.

In some embodiments, the substrate processing system 100 may further include a second gas manifold 112 that is connected to second gas sources 114, e.g., gas chemistry supplies from a facility and/or inert gases. Depending on the processing being performed over a bottom surface of the substrate 128, the control module 120 may control the delivery of second gas sources 114 via the second gas manifold 112. The chosen gases may then be flown into the showerhead 104 and distributed in a space volume defined between a face of the show-ped 106 that faces an under surface or under side (e.g., backside) of the substrate 128 when the substrate 128 is resting over the spacers 130. The spacers 130 may provide for a separation that optimizes deposition to the under surface of the substrate 128, while reducing deposition over the top surface of the substrate 128. In some embodiments, while deposition is targeted for the under surface of the substrate 128, an inert gas may be flown over the top surface of the substrate 128 via the showerhead 104, which may push reactant gases away from the top surface and enable reactant gases provided from the show-ped 106 to be directed to the under surface of the substrate 128.

Further, the gases may be premixed or not. Appropriate valving and mass flow control mechanisms may be employed to ensure that the correct gases are delivered during the deposition and plasma treatment phases of the process. Process gases may exit the chamber 102 via an outlet. A vacuum pump (e.g., a one or two stage mechanical dry pump and/or a turbomolecular pump) may draw process gases out and maintains a suitably low pressure within the reactor by a close loop controlled flow restriction device, such as a throttle valve or a pendulum valve.

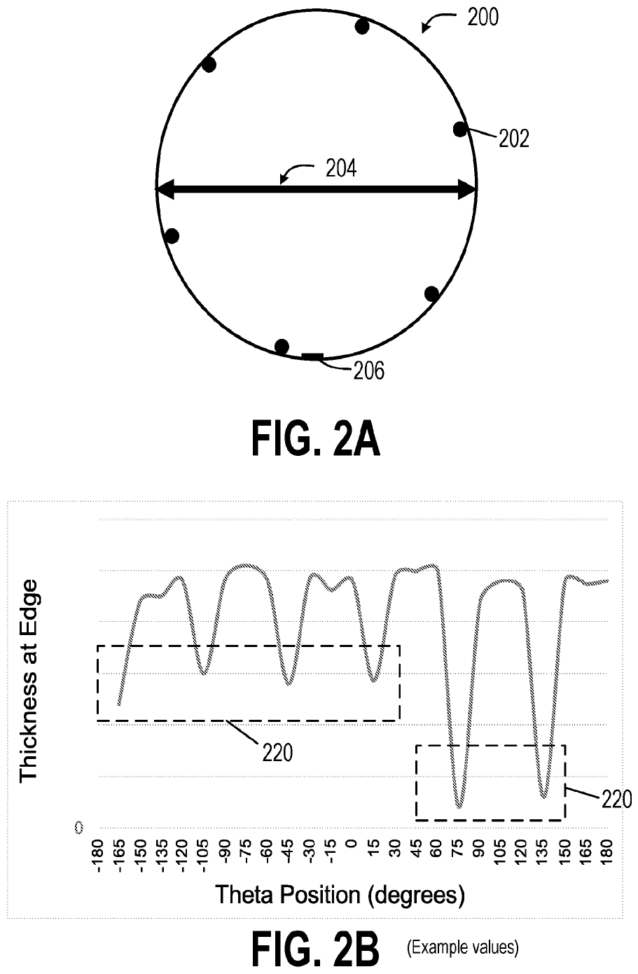

In some embodiments, a carrier ring 124 may encircle an outer region of the show-ped 106. When the top surface of the substrate 128 is being processed, e.g., a material is being deposited thereon, the carrier ring 124 may be configured to sit over a carrier ring support region that is a step down from a wafer support region in the center of the show-ped 106. The top surface of the carrier ring 124 is generally coplanar with the top surface of the substrate 128. The carrier ring 124 may include an outer edge side of its disk structure, e.g., outer radius, and a wafer edge side of its disk structure, e.g., inner radius, that is closest to where the substrate 128 sits. The carrier ring 124 may be associated with an inner diameter (ID). The inner diameter may extend to an inner perimeter of the carrier ring and generally surround a substrate (e.g., substrate 128) in a processing chamber. The wafer edge side of the carrier ring 124 may also include a plurality of contact support structures or “tabs” which may be configured to lift the substrate 128 when the carrier ring 124 is held by the spacers 130. The carrier ring 124 may include a plurality of tabs with a quantity selected from a range (e.g., six tabs are shown in FIG. 2A described below) to support the substrate 128 during processing. Additional details regarding embodiments of the tabs will follow.

FIG. 1B is a block diagram that illustrates another substrate processing system 150 used to perform processing on the substrate 128, according to some embodiments. In some embodiments, spider forks 132 may be used to lift and maintain the carrier ring 124 in its process height, e.g., to allow depositing in the under surface (backside) of the substrate 128. The carrier ring 124 may therefore be lifted along with the substrate 128. In some implementations, the carrier ring 124 may be rotated to another station, e.g., in a multi-station system.

### Film Thickness Variations

FIG. 2A is a simplified diagram of a carrier ring 200 and locations of tabs 202, according to some embodiments. In some embodiments, six tabs 202 may be disposed about an inner perimeter of the carrier ring 200. Carrier ring tabs may create “shadows” where backside deposition layers are not deposited on a substrate that is placed on the carrier ring, or the backside deposition layers are deposited less than on regions outside the tab shadows.

In some embodiments, the carrier ring 200 may have an inner dimension 204, e.g., 299.0 mm. In some embodiments, a notch tab 206 may be present. The notch tab 206 may assist in blocking plasma from reaching the front side of the substrate, as substrates typically include a wafer notch that may be susceptible to such leakage. The notch tab 206 may assist in alignment of a semiconductor substrate with the carrier ring such that the substrate is in a desired orientation (e.g., for the aforementioned plasma blocking) before processing occurs on the substrate. Processing may result in, e.g., a film being deposited in a backside of the substrate, as described elsewhere herein.

FIG. 2B is a graph of thickness of the film with respect to example angular positions of the carrier ring 200. Thickness of the film may be uneven across the surface of the substrate. In particular, in six angular positions corresponding to the locations of the six tabs 202 of FIG. 2A, the thickness of the deposited film is relatively lower. In this case, the six tabs have greatly reduced the film thickness at the edge of the substrate, as indicated by boxes 220.

Obstructions to deposition created by the tabs 202 as illustrated by FIGS. 2A and 2B present an opportunity to increase the amount of deposition, e.g., by allowing more processing gases to diffuse underneath the tabs. Increasing the amount of deposition offers advantages, such as more of the substrate being used during processing (reduction of shadowing effect, and space-and cost-efficient usage of “real estate”) and/or impedance variation at the carrier ring being reduced.

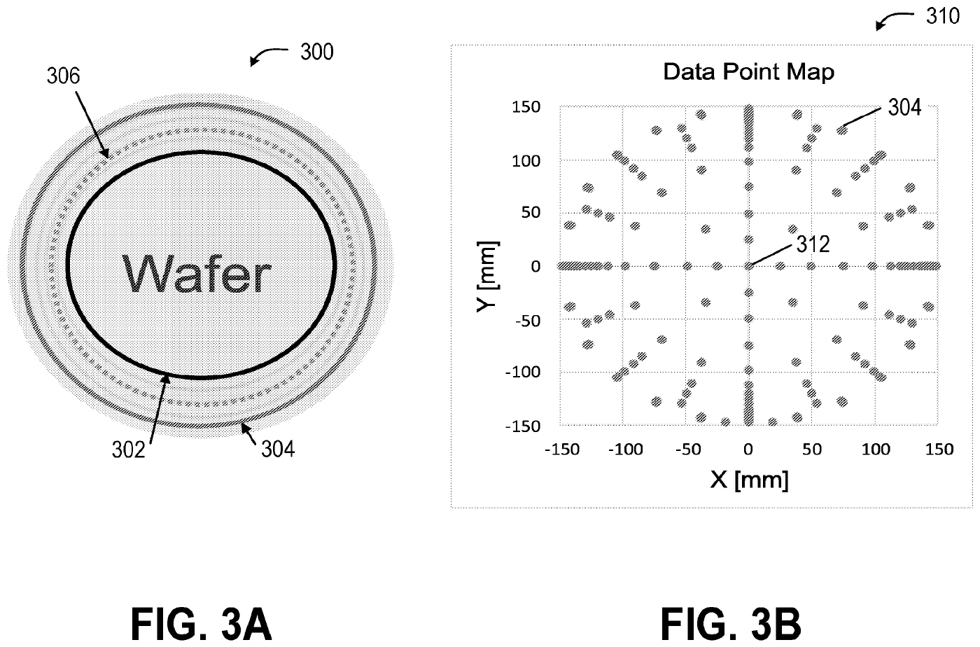

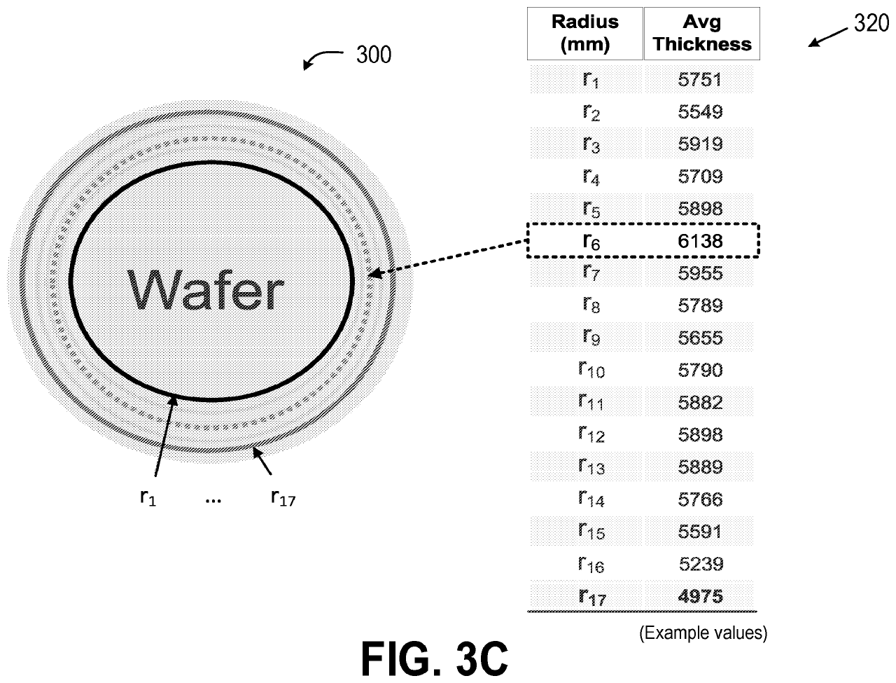

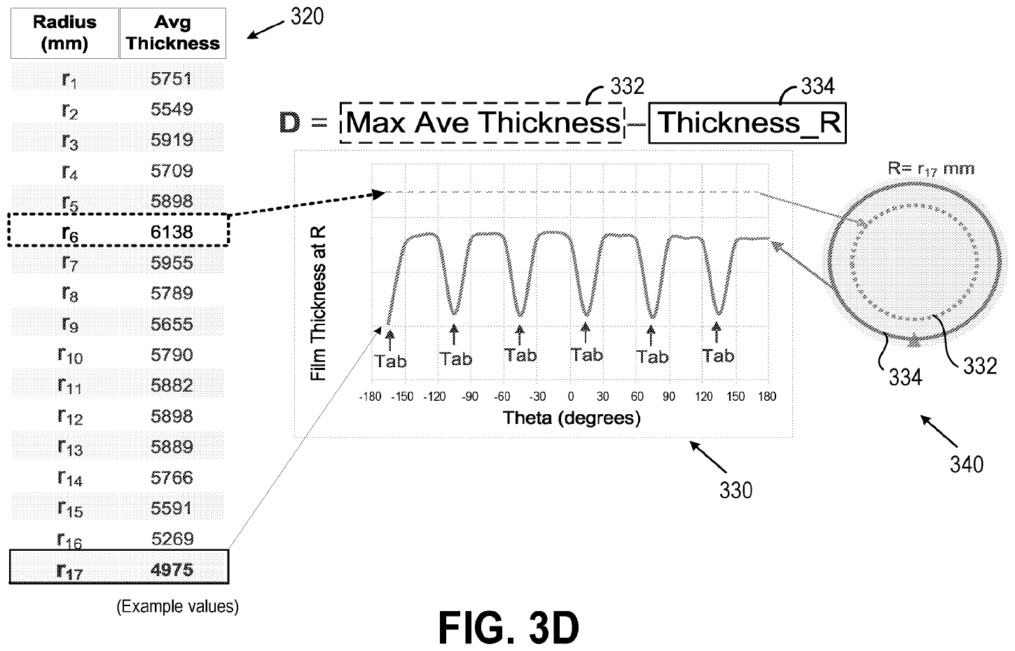

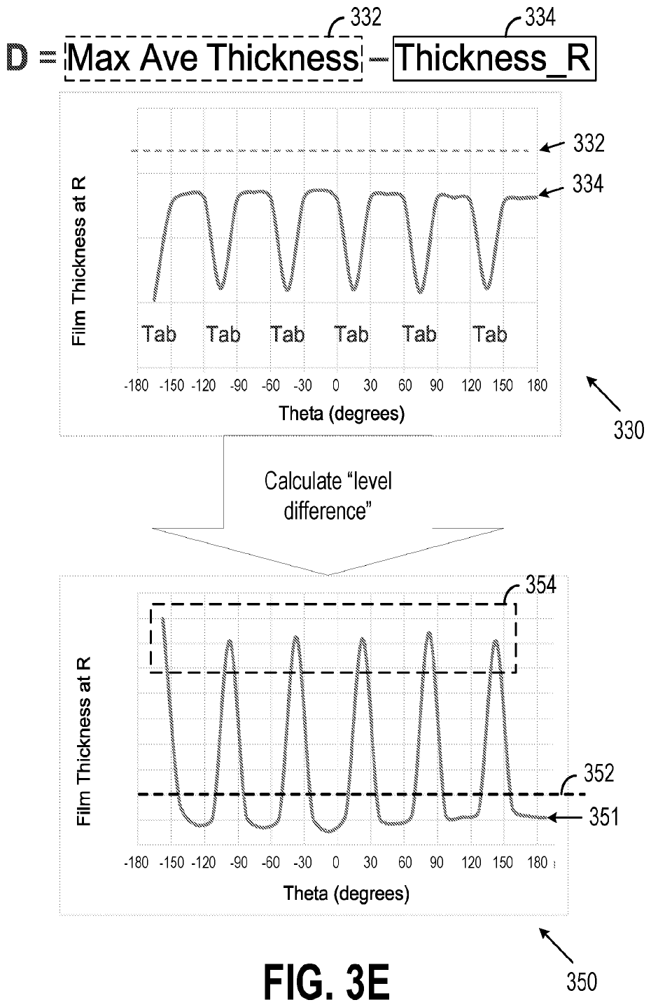

FIG. 3A is a diagram illustrating a semiconductor substrate 300 and various concentric radial points. For example, a first radial point 302 is r₁ mm from the center point of the semiconductor substrate 300, and a second radial point 304 is r₁₇ mm from the center point. A third radial point 306 is r₆ mm from the center point. Various other radial points may be seen in FIG. 3A, between the range from the aforementioned r₁ and r₁₇ radii. In one scenario, thickness variations and local deviations from planarity may mostly occur starting at a radius of r₁ mm. r₁, r₆, and r₁₇ represent the radius from the center point of the semiconductor substrate 300. Example values of these radii may range from 120 mm to 148.2 mm, although myriad different values and ranges (e.g., below 120 mm and/or above 148.2) may be evaluated depending on the semiconductor substrate and its implementation.

FIG. 3B is a map 310 illustrating a map of example radial data points, defined by x-y coordinates with the center being in the origin 312 of a circle corresponding to the shape of the semiconductor substrate 300. The second radial point 304 corresponding to a radius of r₁₇ mm may also be seen in FIG. 3B.

FIG. 3C is a table 320 indicating example average thicknesses of deposited film at various radii. For example, at a radius of r₆ mm, let us assume that the average deposition thickness is determined to be 6138 arbitrary units (for example, nanometers (nm)). The film thickness may be measured using conventional means or measurement tools, e.g., spectroscopic ellipsometry, thickness monitors, interferometers, surface profilers, or scanning electron microscopy. Notably, in this example, the average thickness of r₆=6138 arbitrary units is the highest of all the average thicknesses measured from a radius of r₁ mm to r₁₇ mm.

FIG. 3D is a graph 330 illustrating differences between the example maximum average film thickness 332 and a given film thicknesses 334 along angular positions of a circle defined by a given radius along a carrier ring. In the example of FIG. 3D, a radius of r₁₇ mm—the outer-most radius measured—has been selected for comparison with the example maximum average film thickness 332 (r₆). The graph 330 indicates the example maximum average film thickness 332 in a dotted line, and the given film thicknesses 334 in a solid line representing data points (e.g., corresponding to the map 310 shown in FIG. 3B), where the data points correspond to measured thicknesses at respective radial positions (in degrees). The given film thicknesses 334 indicate that the thicknesses may be relatively lower at angular positions corresponding to tabs (e.g., tabs 202 shown in FIG. 2A). A simplified diagram 340 indicating the two radii of r₆ mm and r₁₇ mm of the substrate is also illustrated.

Using the foregoing data, e.g., data points associated with map 310, data points associated with table 320, and/or data points associated with graph 330, “level differences” (D) between the maximum average film thickness and given film thicknesses 334 may be measured. Existing measurement techniques may merely measure a percentage of nonuniformity or an average film thickness, providing an aggregate measure of uniformity. The level difference can indicate film thickness deltas at discrete points and be a clearer indication of the severity of the how wide the range of thicknesses can be. FIG. 3E shows a graph 350 that indicates example level differences along angular positions, determined by subtracting given film thicknesses 334 by the example maximum average film thickness 332. The solid line 351 indicating level difference clearly highlights the deltas between the angular positions corresponding to the tabs, where peaks 354 are.

Performing photolithography or other downstream process that relies on substrate uniformity, with little or no deviation from true planarity anywhere on the substrate, can introduce errors, particularly in regions of the substrate where less backside material was deposited. Hence, it is desired to keep the level difference below a certain amount. In some example applications, it may be specified that level differences should remain below a prescribed amount of arbitrary units, e.g., below dashed line 352. One such example may be 700 nm. The foregoing “level difference” problem where the level difference is measured to be above a certain amount (e.g., peaks 354 where the tabs are located where D is above the dashed line 352 or another threshold level) may indicate that the resulting substrate has uneven film deposition and/or unrealized deposition potential at the tab locations. In some cases, depending on the application, configuration (e.g., quantity, physical shape) of tabs and/or carrier rings, and/or the resulting bow post-processing, a level difference above a certain amount (e.g., dashed line 352) may result in yield loss and/or slower processing of the substrate (e.g., a slower lithography process), which can be a costly or time-consuming, and hence undesirable, result.

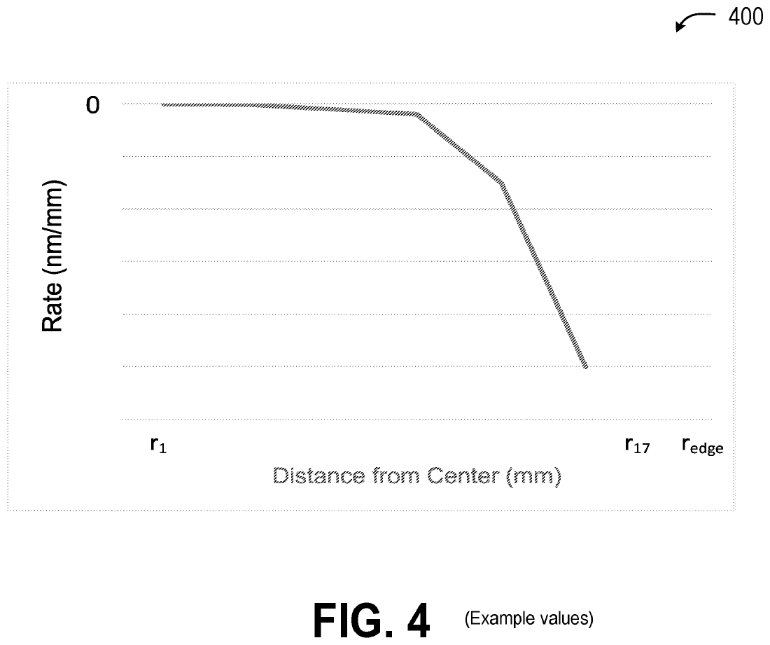

Moreover, FIG. 4 is a graph 400 that illustrates example changes in thickness differences with respect to the radius of a substrate placed on a carrier ring. As illustrated, the film thickness relative to center portions of the substrate (e.g., above a radius r₁ mm) may drop faster (a “derivative” of thickness change) as the radius approaches the far edge of the substrate (e.g., a radius proximate to r₁₇ mm). Portions of carrier rings (e.g., portions that a substrate may abut) may physically at least partially block reactions with deposition gases, for example. In some cases, thickness may drop to zero at the very edge of the substrate (e.g., near a radius of r_{edge} mm). In addition to the aforementioned problem where the level difference spikes at tab locations (thickness variation with respect to radial positions), the drop in thickness near the edge of the substrate (an “edge effect” of thickness variation with respect to radial distance) may contribute to uneven film thickness. However, it is desired to keep the film thickness consistent across the entire radius of the substrate during substrate processing.

Therefore, the present disclosure describes optimized carrier rings and associated structures (e.g., tabs) that, among other things, minimizes substrate contact area (which increases deposition areas near the substrate edges and thus increases the evenness of film thicknesses) and minimizes the edge effect.

### Carrier Ring Configurations

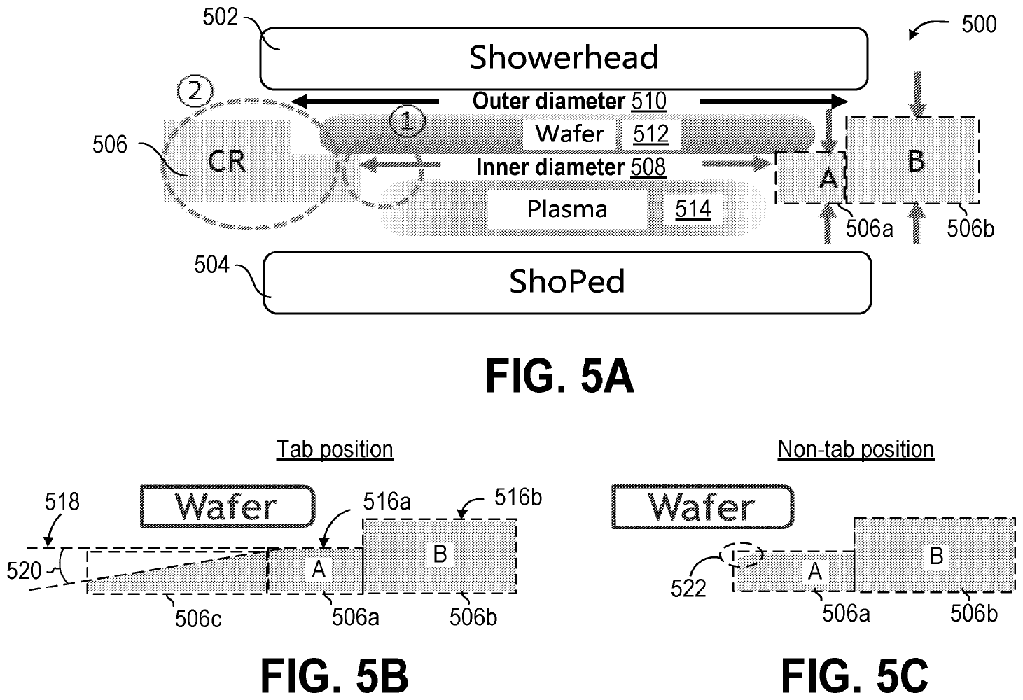

FIG. 5A is a simplified diagram that illustrates components of a substrate processing system 500, according to some embodiments. In some embodiments, substrate processing system 500 may be an example of the substrate processing system 100 or 150. Substrate processing system 500 may include a showerhead 502 disposed over a show-ped 504. A carrier ring 506 may be disposed between the showerhead 502 and show-ped 504, and may be a structure having a ring-like shape. A cross-section the carrier ring 506 is shown in FIG. 5A, with cross-sectional portions 506a (also labeled “A”) and 506b (also labeled “B”). These cross-sectional portions may have symmetry; the dimensions of the cross-sectional portions may apply substantially equally to every cross-section. For example, cross-sectional portion 506a may have a thickness measuring about 0.1 to 0.5 mm (e.g., 0.3 mm in some embodiments) all around the carrier ring 506, and cross-sectional portion 506a may have a thickness measuring about 0.3 to 0.7 mm (e.g., 0.5 mm in some embodiments) all around the carrier ring 506. The carrier ring 506 may have with an inner diameter (ID) 508 and an outer diameter (OD) 510 that allow a substrate (e.g., wafer 512) to be placed on the carrier ring 506, e.g., above the “A” portion and abutting the “B” portion. The wafer 512 may have a circular shape to fit into the carrier ring 506. Plasma 514 may be formed or extinguished under the wafer 512.

In some embodiments, the carrier ring ID 508 may be selected from a diameter of 298.4 to 299.5 mm. For example, the carrier ring ID 508 may in some cases have a diameter of 299.0 mm. Thus, with a carrier ring ID of 299.0 mm, a 300-mm wafer may rest on the carrier ring 506 and have the vast majority of the back surface of the wafer exposed for processing (backside deposition, etching, etc.).

FIGS. 5B and 5C are close-up diagrams of cross-sectional portion of the carrier ring 506, according to some embodiments. In some portions of the carrier ring 506, as shown in FIG. 5B, the inner diameter includes a tab 506c. In some embodiments, the tab 506c may be a support structure for the wafer 512. The tab 506c may, for example, prevent the wafer 512 from falling through the carrier ring 506. In some implementations, the tab 506c may have a sloped or tapered surface, with an angle 520 with respect to one or more of the top surfaces 516a, 516b of the cross-sectional portions 506a, 506b. In various implementations, the angle 520 may be neither parallel to nor perpendicular to a plane associated with a top surface 516a or 516b (or both). In some cases, the angle 520 may be between about 5 to 20 degrees, e.g., about 15 degrees or less, e.g., about 11.1 degrees, from a plane 518 defined by the top surface 516a. The top surface 516a from which the tab inwardly extends may interface with (e.g., support via physical contact with) the wafer 512.

In some implementations, a plurality of tabs may be positioned about the inner diameter of the carrier ring 506. Further, the plurality of tabs may be inwardly extending tabs have outer edges attaching to the ring and defining the inner diameter. In some cases, the inner diameter may be selected from a range of 296.0 to 299.5 mm, for example, 297.0 mm. A quantity of the plurality of tabs may be selected (e.g., at least 8, or a quantity selected from a range of at least 5 to at most 15, or at least 8 to at most 15, e.g., 12) to ensure that the wafer 512 does not fall through the carrier ring 506 (e.g., in the event that one or more of the tabs deform or break off) nor create a tilt of the wafer 512 when it is placed on the carrier ring 506. It is essential to keep the wafer entirely level because processing on a tilted wafer may render the resulting depositions, etchings, etc. partly or wholly unusable. For example, a good image cannot be acquired for lithography; e.g., line widths may be lost. If there are fewer tabs than a certain quantity (e.g., 3 or 4), the carrier ring 506 may still be at risk of tilting or falling through, e.g., when moved. If there are more tabs than a certain number (e.g., 15), excessive diminishing returns may be introduced from unnecessary blockage of surface area (e.g., for backside deposition) and/or unnecessary manufacturing costs for the carrier ring 506.

In some portions of the carrier ring 506 as shown in FIG. 5C, the inner diameter does not have a tab, as illustrated by the cross-sectional portion 506a having a relatively non-tapered surface. However, in some embodiments, the cross-sectional portion 506a may have an angled portion 522. Positions that include the tab, such as that shown in FIG. 5B, may have an angled portion that continues to extend into the tab 506c.

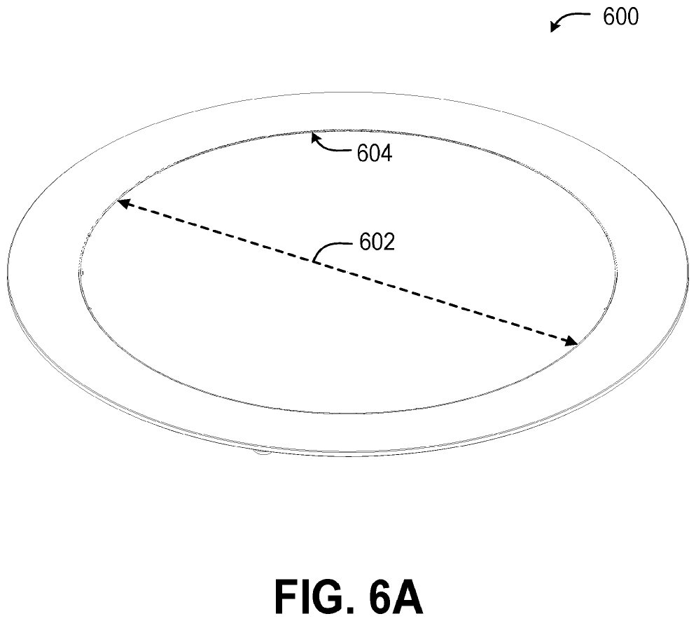

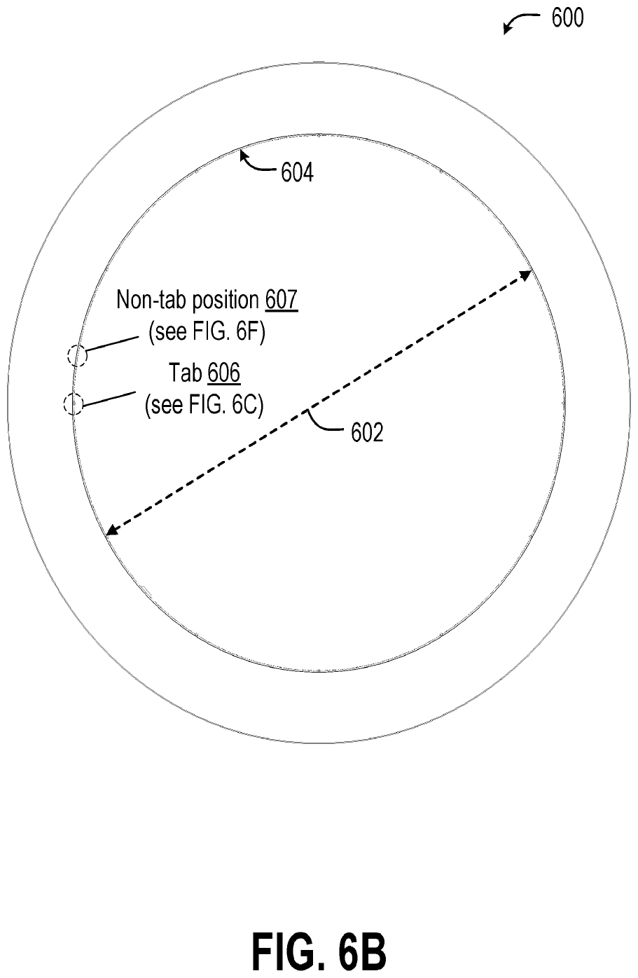

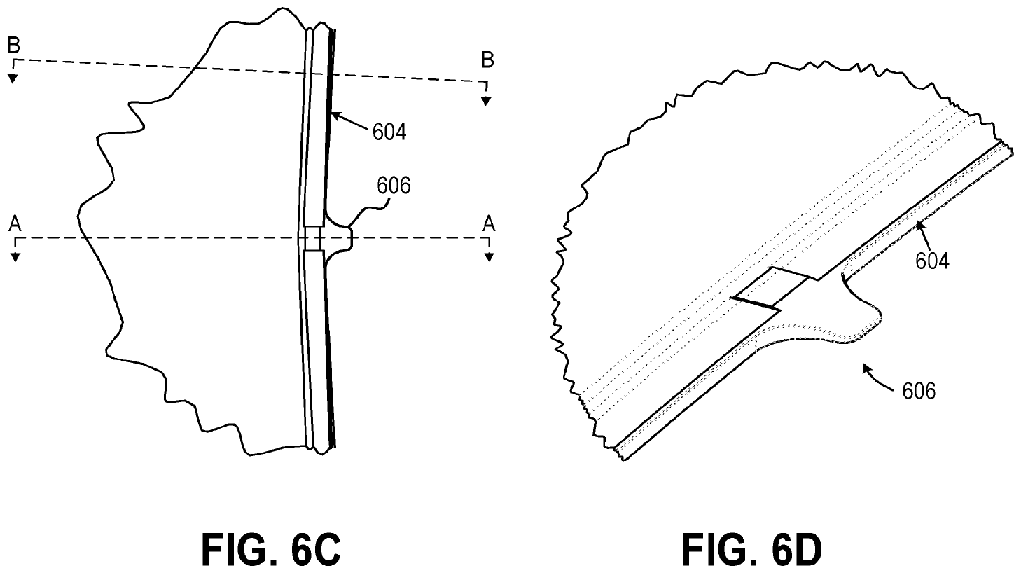

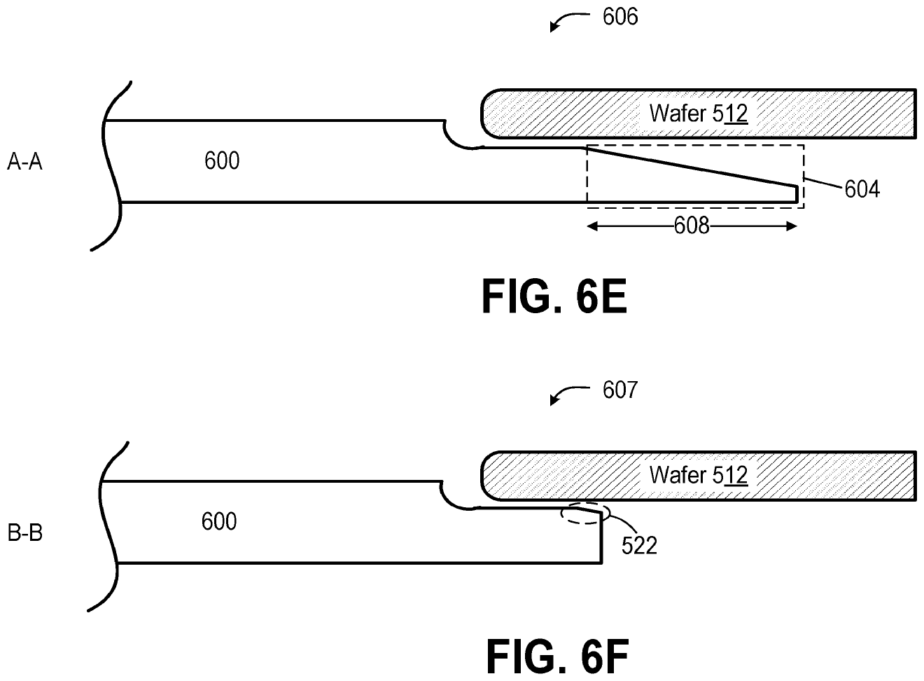

FIG. 6A is a perspective view of a carrier ring 600, according to some embodiments. In some embodiments, the carrier ring 600 may be an example of carrier ring 506 as described with respect to FIG. 5A. The carrier ring 600 may have an inner diameter 602 that is measured between one end of an inner perimeter 604 to the opposing end of the inner perimeter 604. The inner perimeter 604 may be defined by an inner wall of an inner portion of the carrier ring 600, where the cross-sectional portions 506a is an example of the inner portion. In some implementations, the inner diameter 602 may be selected from a range of 298.4 mm to 299.5 mm. An example of the inner diameter 602 may be 299.0 mm.

FIG. 6B is a top-down view of the carrier ring 600, according to some embodiments. The inner diameter 602 of the carrier ring 600 may extend between opposing ends of the inner perimeter 604, as also shown in FIG. 6A. In some embodiments, a plurality of inwardly extending tabs, such as tab 606 may be disposed about the inner perimeter 604 (of the inner portion) of the carrier ring 600, separated by non-tab positions 607. A great majority of the inner perimeter does not have a tab, and may have the non-tab cross-section configuration such as that depicted in FIG. 5C.

In various implementations of the carrier ring 600, 5 to 15 tabs may extend inwardly from the inner perimeter 604 of the carrier ring 600. For example, in one such implementation, 12 tabs may be disposed about the inner perimeter 604. In some cases, the tabs may be spaced apart by a substantially equal distance from one another. However, in some cases, the tabs may be spaced in prescribed positions that are not equal in distance to one another. For example, tabs may be grouped together, e.g., in groups of two and placed in six equidistant and/or equiangularly positions. In other cases, other grouping schemes may be possible, e.g., equal groups of three, four, or six, groups of unequal quantities.

FIG. 6C is a top-down, close-up view of a tab 606, according to some embodiments. FIG. 6D is a perspective view of the tab 606, according to some embodiments. In some embodiments, the tab 606 is inwardly extending or protruding so as to at least partly support or provide a support for a semiconductor substrate, e.g., wafer 512. FIG. 6E is a cross-sectional view of the tab 606 and the carrier ring 600 across cross-section A-A of FIG. 6C, according to some embodiments.

In some embodiments, the tab 606 may have a sloped top surface, creating an angle with respect to a plane defined by the top surface of the inner perimeter 604. In some implementations, the angle may be about 11.1 degrees. This angle may be selected from a range, e.g., 5 to 20 degrees inclusive, or 10 to 12 degrees inclusive. In other implementations, the angle may be neither parallel to nor perpendicular to the plane, e.g., may have an angle selected from 15 degrees or below, or 10 degrees or below. The sloped surface of the tab may allow, e.g., deposition gases to reach the backside surface of the substrate. In some cases, some tabs may have different angles from one another. For example, at least one of the tabs may be sloped at 11.1 degrees from the plane, and at least another one of the tabs may be sloped at 5 degrees from the plane. In some cases, the angle may be shaped to not be uniform through the length of the tabs. The angle may be measured at a base of the tab, closest to the inner diameter of the carrier ring. In some cases, some tabs may not have a sloped top surface, in which case, non-sloped tabs may be placed at a lower height relative to the sloped tabs so as to prevent direct contact of the non-sloped tabs with the substrate.

In some embodiments, the tabs may have an inner diameter selected from a range of 296.0 to 299.5 mm, for example, 297.0 mm. In some cases, the inner diameter of the tabs may be defined by inner edges of the tabs defining a circle; that is, the inner edges defining the circle may have a diameter of 296.0 to 299.5 mm, e.g., about 296.0 to 298.5 mm, e.g., 270.0 mm. In some embodiments, the tab 606 may have a maximum length (e.g., length 608 as shown in FIG. 6E) of 10.0 mm. That is, in some implementations, the tab 606 may have a length 608 of below 10.0 mm, e.g., 2.0 mm, 1.5 mm, 1.0 mm. In some cases, some tabs may have different lengths from one another. For example, at least one of the tabs may be 2.0 mm long, and at least another one of the tabs may be 1.5 mm long.

In some embodiments, the tab 606 may have a maximum width of 2.0 mm. That is, in some implementations, the tab 606 may have a width of below 2.0 mm, e.g., between 0.5 to 1.5 mm, e.g., 1.0 mm. In some embodiments, the tab 606 may have a minimum width of about 0.5 mm. In some cases, some tabs may have different widths from one another. For example, at least one of the tabs may be 1.0 mm wide, and at least another one of the tabs may be 0.7 mm wide. In some cases, the width may not be uniform through the length of the tabs. The width may be measured at the terminating end portion of the tab, and tabs may become wider or narrower than, e.g., 1.0 mm, along the length of the tabs.

FIG. 6F is a cross-sectional view of a non-tab position 607 and the carrier ring 600 across cross-section B-B of FIG. 6C, according to some embodiments. In some embodiments, the inner perimeter may include an angled portion at at least one of the edges, such as the angled portion 522 depicted in FIG. 5C.

In different implementations of the carrier ring 600 or inwardly extending tabs (e.g., tab 606), quantity of tabs, angle of tabs, inner diameter of carrier ring, length of tab, and/or width of tab may be selected based on the type of gases used, the presence of plasma, need for substrate real estate, and/or the application. The dimensions described above may be summarized as follows.

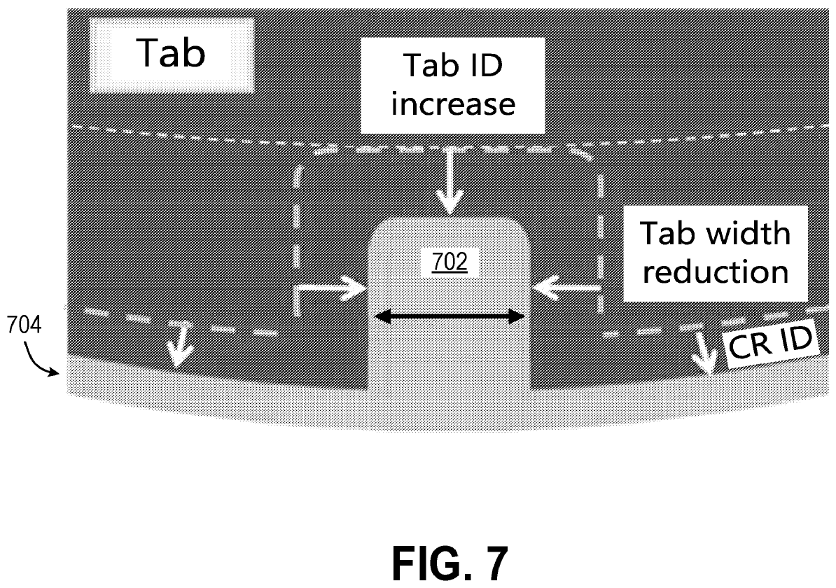

In some embodiments, the carrier ring 704 may have an inner diameter selected from a range of about 298.4 mm to 299.5 mm, for example, 299.0 mm. In some embodiments, the carrier ring 704 may include a plurality of tabs (one of the tabs shown). In some implementations, the plurality of tabs may have an inner diameter selected from a range of 296.0 to 299.5 mm, for example, 297.0 mm. In some implementations, the quantity of the plurality of tabs may be selected from a range of at least 5 up to an upper limit of 15 (for example, 12), above which the tabs may provide diminishing returns. In some embodiments, the width of at least one tab 702 may be a width of about 0.5 to 2.0 mm, for example, 1.0 mm. In some embodiments, the length of at least one tab 702 may have a maximum length of about 10.0 mm. In some implementations, a downward-sloping angle with respect to a top surface of at least one tab 702 may be selected from a range of 15 degrees or less, for example, 11.1 degrees. FIG. 7 is a diagram illustrating one example embodiment possessing various optimizations associated with at least one tab 702 of a carrier ring 704.

The foregoing physical characteristics of the carrier ring 704 and/or at least one tab 702 of the carrier ring 704 represent, in some cases, reductions or increases of certain dimensions or parameters associated with tabs and carrier rings. For example, the tab may have a larger inner diameter, the tab width and/or length may be reduced, and/or the tab may include a sloped portion to accommodate increased deposition by, e.g., allowing more processing gases to reach the backside area. Moreover, the carrier ring may have a larger inner diameter so as to minimize the edge effect. However, smaller tabs and a larger inner diameter may increase the potential that a substrate held and supported by the carrier ring 704 may become unstable and susceptible to, e.g., tilting. For example, there may be a greater potential of the substrate tilting while nested on the carrier ring, or falling through the inner perimeter of the carrier ring. Hence, to further accommodate the potential risk, the number of tabs may be increased (e.g., to 12) to prevent such risk.

As one example embodiment, at least one tab 702 may have a width measuring about 1.0 mm, a length measuring about 2.0 mm, and a downward sloping angle measuring about 11.1 degrees. Further, the carrier ring 704 may have an inner diameter measuring about 299.0 mm and 12 tabs positioned substantially equidistantly and/or substantially equiangularly.

In other examples, the foregoing considerations may be balanced. Consider an implementation in which the width is selected to be slightly smaller (e.g., a width of 0.8 mm). To accommodate the smaller tabs, the number of tabs may be increased (e.g., to 14 or 15) for example, to ensure that the substrate does not fall or tilt. Consider another implementation in which a smaller inner diameter is prioritized (e.g., 298.5 mm). Given the increased stability of the substrate, the angle may be greatly increased to ensure that processing gases reach the tab areas. Each of these implementations, and myriad other combinations of these ring and tab characteristics, may contribute to reducing level differences, minimizing the substrate contact area (e.g., minimum contact area as discussed below), and ultimately minimizing the edge effect (e.g., softening the transition of film thickness with respect to radial distance) and enabling consistent film thicknesses. Moreover, the minimization of the substrate contact area based on the aforementioned physical characteristics of the tabs (including the selection of the inner diameter of the carrier ring, the inner diameter of the tabs, the quantity of the tabs, the width of the tabs, the downward angle of the tabs, or a combination thereof) enables more backside deposition to the substrate (e.g., the locations of the substrate corresponding to the tabs) as compared to another carrier ring having tabs that do not have these physical characteristics. For example, the tabs of the other carrier ring (without the aforementioned physical characteristics) would be larger and therefore reduce, e.g., backside deposition. FIG. 7 indicates the comparison via an increase in the inner diameter of the at least one tab 702 and the reduction of the width of the at least one tab 702.

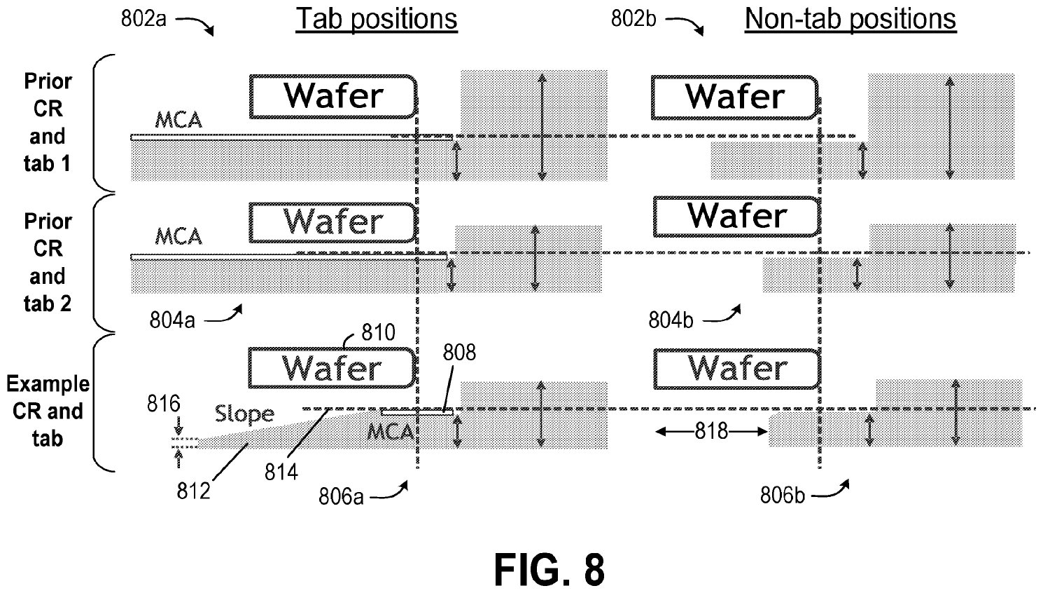

FIG. 8 depicts comparisons between existing carrier rings and tabs, and an example carrier ring and tab disclosed herein, at tab positions and non-tab positions, according to some embodiments. In some embodiments, the example carrier ring and tab 806a may be characterized by a smaller minimum contact area (MCA) 808 as compared to prior implementations 802a and 804a. MCA may refer to an area of the carrier ring (e.g., top surface of an inner portion of the carrier ring) that may interface with (e.g., make physical contact with and/or support) a substrate (e.g., wafer 810). It is desirable to decrease or minimize MCA for reasons such as increasing deposition area on the backside of the wafer 810 and reducing particles. Particles may refer to foreign objects (e.g., dust particles) that obstruct deposition, etching, or other processes performed on the wafer 810, and may originate from or be caused by contact with other surfaces such as the carrier ring. Hence, by reducing contact area with the carrier ring, particle formation may be minimized.

In some embodiments, the example carrier ring and tab 806a may be characterized by a sloped tab portion 812. In some implementations, the slope may be at an angle that is 15 degrees or less (e.g., about 11.1 degrees), where the angle is measured with respect to a plane 814 defined by a top area of the inner portion of the carrier ring. The sloped tab portion 812 may terminate at an end portion having a prescribed height (e.g., about 0.09 mm). In some variants, such height may be variable according to the geometry and physical characteristics of the tab (e.g., angle of slope, inner diameter or length of tab).

In contrast, in prior implementations 802a and 804a, the MCA may be significantly larger. Moreover, no slope may exist at the tab. Thus, a wafer 810 may make greater contact with the carrier ring.

In some embodiments, non-tab positions of the example carrier ring and tab 806b may further offer decreased MCA by virtue of, e.g., a reduced carrier ring inner diameter 818 as compared to that of one or more of the existing implementations 802b, 804b. In some embodiments, the thickness of the carrier ring may also be reduced. In some implementations, the thickness of the inner portion and the outer portion of the carrier ring may measuring about 0.3 mm and 0.5 mm, respectively. The smaller thicknesses of the inner and outer portions may assist with tuning or matching wafer impedance, which may result in more uniform deposition and minimization of the aforementioned edge effect.

### Backside Grounding

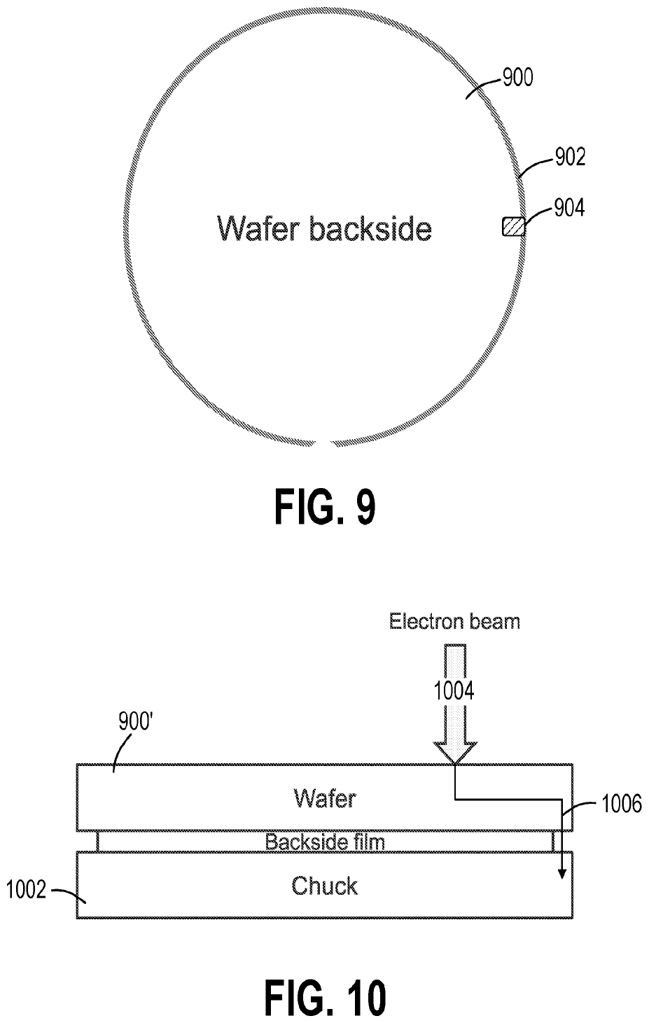

FIG. 9 is a diagram of a semiconductor wafer 900 positioned on a carrier ring 902 having a plurality of tabs, according to some embodiments. The back of the semiconductor wafer 900 and the carrier ring are depicted to illustrate one tab 904 of the plurality of tabs. In some embodiments, some or all of the plurality of tabs may be an example of the inwardly extending tabs as discussed above, e.g., with respect to FIGS. 5A-8. That is, the tabs may have physical characteristics (tab ID, smaller width, angle of slope, etc.) selected from the specified ranges as discussed above. Processing (backside deposition, etching, etc.) may be performed on the semiconductor wafer 900 while it is supported by carrier ring 902 and tabs, including tab 904.

It is understood that the foregoing is equally appliable to some or all of the tabs that may be present on the carrier ring 902. According to some implementations, there may be up to 6, 8, 12, or 15 tabs, some or all of which may have the physical characteristics as discussed herein with respect to the FIGS. 5A-8 embodiments.

FIG. 10 is a diagram of a processed wafer 900′ (e.g., from FIG. 9) that may be clamped onto a pedestal chuck 1002 (e.g., an ESC), according to some embodiments. One potential cause of failure during subsequent processing on the processed wafer 900′ is that when the backside of the processed wafer 900′ has been coated entirely, a current charge may build up. This can result in deleterious effects. For example, electrons may be deflected from application of an electron beam 1004.

However, some shadowing effects may remain from the tabs and/or the inner perimeter of the carrier ring 902 as described herein (including FIG. 9). By preserving some regions without deposition underneath the carrier ring tabs, a clear conductive path 1006 may be provided as a conductive grounding point between the pedestal chuck 1002 and the processed wafer 900′. In some embodiments, multiple conductive grounding points may be present as a result of preserving multiple regions without deposition underneath the carrier ring tabs (e.g., one conductive grounding point or area per carrier ring tab).

Since the larger the grounding path, the less backside deposition occurs, the shadowing effects from the tabs may be an additional factor to balance with aforementioned considerations. Such other considerations to balance may include increasing the deposition areas, lowering the level differences, preventing front side deposition while allowing backside deposition, and preventing the processed wafer 900′ from tilting or falling through the inner perimeter of the carrier ring.

For instance, some embodiments of the carrier ring and tabs as described herein may balance, depending on the application or the desired outcome, the desirability of a reduction of level difference or a reduction in MCA (based on, e.g., carrier ring ID, tab ID, tab width, tab angle,) against allowing open electrical contact region using more contact areas. However, in some cases, allowing more of the open electrical contact region may also be accomplished by having additional tabs, e.g., 12 or more, with some being non-sloped and making contact with the processed wafer 900′. Myriad combinations of the physical characteristics of the disclosed embodiments of the carrier ring and tab may be balanced to achieve the advantages described herein.

### Methods

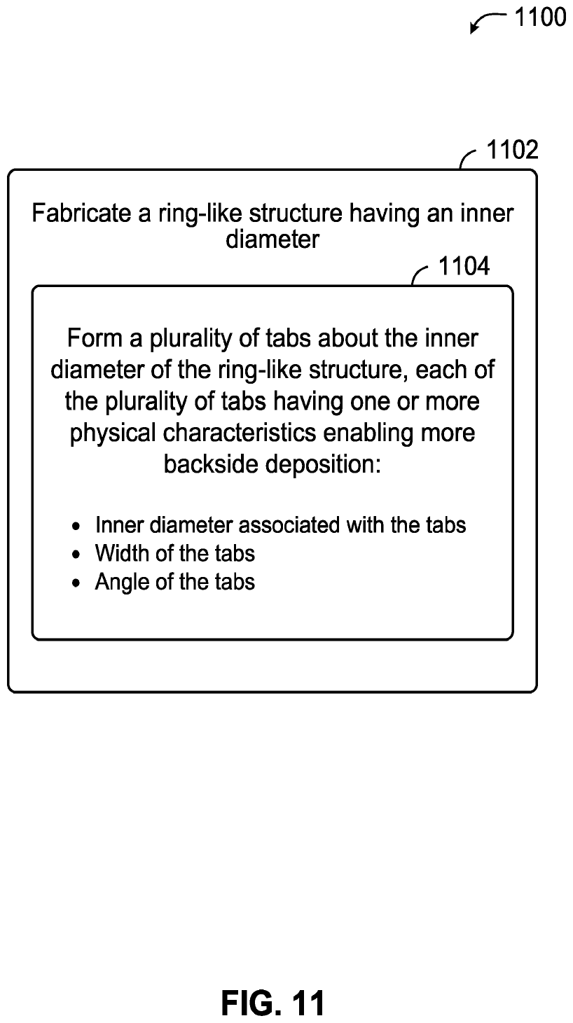

FIG. 11 is a flow diagram illustrating a method 1100 for obtaining an apparatus configured to support a semiconductor substrate, according to some embodiments. One or more of the functions of the method 1100 may be performed by or caused by a computerized apparatus or system. Means for performing the functionality illustrated in one or more of the steps shown in FIG. 11 may include hardware and/or software components of such computerized apparatus or system, such as, for example, a controller apparatus, a computerized system, or a computer-readable apparatus including a storage medium storing computer-readable and/or computer-executable instructions that are configured to, when executed by a processor apparatus, cause the at least one processor apparatus or a computerized apparatus to perform the operations. A controller may be one example of the computerized apparatus or system. A process chamber may be another example of the computerized apparatus or system. Example components of a process chamber (including a controller) are illustrated in FIGS. 1A and 1B, described in more detail above.

It should also be noted that the operations of the method 1100 may be performed in any suitable order, not necessarily the order depicted in FIG. 11. Further, the method 1100 may include additional or fewer operations than those depicted in FIG. 11 to obtain the apparatus.

At block 1102, the method 1100 may include fabricating a ring-like structure having an inner diameter. The ring-like structure may have a substantially circular structure (e.g., a carrier ring) having an inner portion and an outer portion. In some embodiments, the inner diameter of the ring-like structure may range from 298.4 to 299.5 mm, and extend from the center of the substantially circular structure to an inner perimeter of the inner portion. In some implementations, the inner diameter may be about 299.0 mm.

At block 1104, the method 1100 may include forming a plurality of inwardly extending tabs about the inner diameter of the ring-like structure. In some embodiments, the number of the tabs may be selected from a range of 5 to 15. In some implementations, there may be 12 tabs positioned about the inner diameter of the ring-like structure. In some variants, the tabs may be formed in equidistant and equiangular positions. In some variants, the tabs may be formed in groups, e.g., two tabs in six positions that are equidistant and equiangular from one another.

In some embodiments, the plurality of inwardly extending tabs may have one or more physical characteristics that enable more backside deposition of the semiconductor substrate as compared to a ring-like structure having a plurality of tabs formed without the one or more characteristics. In some implementations, the one or more physical characteristics may include one or more of an inner diameter associated with the plurality of tabs, a width of the plurality of tabs, and an angle of at least portions of top surfaces associated with the plurality of tabs with respect to a plane defined by the ring-like structure.

In some variants, the inner diameter associated with the plurality of tabs may range from 296.0 to 299.5 mm. In some examples, the tab inner diameter may be about 297.0 mm.

In some variants, the angle of the at least portions of top surfaces may be selected from a range of 15 degrees or less, where the at least portion of the top surfaces are collectively configured to interface with (e.g., make physical contact with and/or support) the semiconductor substrate. In some examples, the angle may be downward about 11.1 degrees with respect to the plane defined by the ring-like structure. In some cases, the angle may be shaped to not be uniform through the length of the tabs. The angle may be measured at a base of the tab, closest to the inner diameter of the carrier ring. Alternatively, an average value of the angles may be selected.

In some variants, width of the plurality of tabs may range from 0.5 mm to 2.0 mm. In some examples, the width of the tabs may be about 1.0 mm. In some cases, the width may not be uniform through the length of the tabs. The width may be measured at the terminating end portion of the tab, and tabs may become wider or narrower than 1.0 mm along the length of the tabs.

The foregoing physical characteristics of the carrier ring and its tabs may contribute to reduced MCA, increased processing or deposition (e.g., on the backside of the semiconductor substrate), reduced particles, reduced edge effect, and ultimately a more consistent film thickness (measurable by, e.g., reduced level differences). More specifically, the foregoing physical characteristics of the tabs allows more backside deposition by virtue of introducing minimal coverage to the backside of the semiconductor substrate, as compared to, e.g., some existing carrier rings that may have larger tabs that cover more of the backside area, which would prevent the amount of deposition that could occur with the carrier ring described herein.

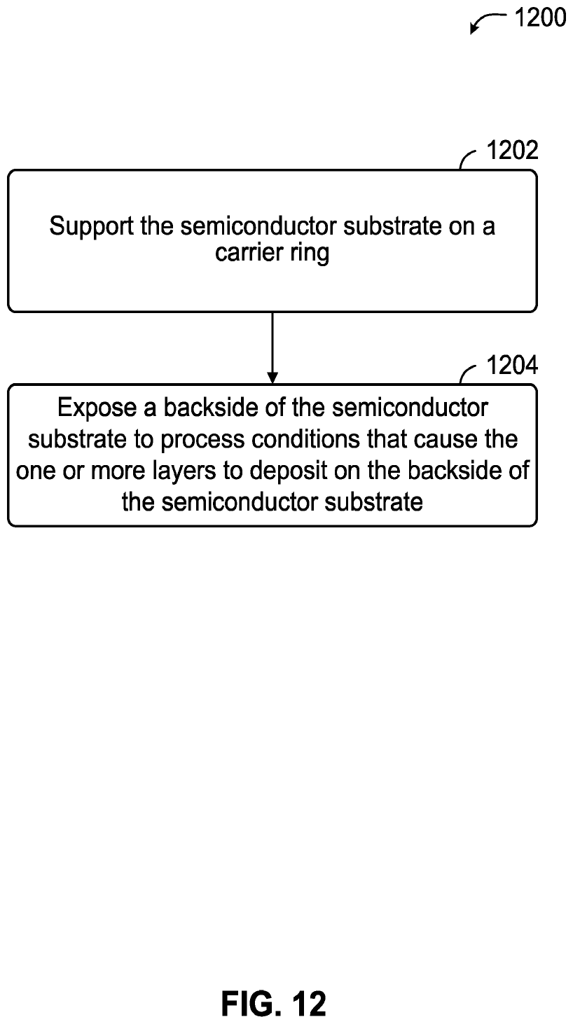

FIG. 12 is a flow diagram illustrating a method 1200 of depositing one or more layers on a backside of a semiconductor substrate, according to some embodiments. One or more of the functions of the method 1200 may be performed by or caused by a computerized apparatus or system. Means for performing the functionality illustrated in one or more of the steps shown in FIG. 12 may include hardware and/or software components of such computerized apparatus or system, such as, for example, a controller apparatus, a computerized system, or a computer-readable apparatus including a storage medium storing computer-readable and/or computer-executable instructions that are configured to, when executed by a processor apparatus, cause the at least one processor apparatus or a computerized apparatus to perform the operations. A controller may be one example of the computerized apparatus or system. A process chamber may be another example of the computerized apparatus or system. Example components of a process chamber (including a controller) are illustrated in FIGS. 1A and 1B, described in more detail above.

It should also be noted that the operations of the method 1200 may be performed in any suitable order, not necessarily the order depicted in FIG. 12. Further, the method 1200 may include additional or fewer operations than those depicted in FIG. 12 to deposit the layers.

At block 1202, the method 1200 may include supporting the semiconductor substrate on a carrier ring. In some embodiments, the carrier ring may be an example of the carrier ring 600 shown in FIGS. 6A-6F, the carrier ring 704 shown in FIG. 7, or the carrier ring shown in FIG. 8. The carrier ring may possess one or more physical characteristics possessed by the foregoing carrier rings, including the specified inner diameter of the carrier ring, inner diameter of a plurality of inwardly extending tabs, quantity of the plurality of inwardly extending tabs, width of the plurality of inwardly extending tabs, and/or angle of the plurality of inwardly extending tabs.

In some embodiments, the semiconductor substrate may be an example of the substrate 128 as shown in FIGS. 1A and 1B. In some embodiments, the semiconductor substrate may be an example of the wafer 512 as shown in FIGS. 5A-5C, 6E and 6F, the wafer shown in FIG. 8, or the semiconductor wafer 900 shown in FIG. 9.

In some embodiments, the semiconductor substrate may be placed on top of an inner portion of the carrier ring and surrounded by an outer portion of the carrier ring. In some implementations, the inner portion may be defined by the cross-sectional portion 506a, and the outer portion may be defined by the cross-sectional portion 506b, as shown in FIGS. 5A-5C.

At block 1204, the method 1200 may include exposing the backside of the semiconductor substrate to process conditions that cause the one or more layers to deposit on the backside of the semiconductor substrate. In some embodiments, the process conditions include exposure to a chemical precursor of at least one of the one or more layers. For example, a silicon-containing reactant, a nitrogen-containing reactant, or an oxygen-containing co-reactant may be used as the chemical precursor. In some embodiments, at least one of the one or more layers on the backside of the semiconductor substrate includes polysilicon, a silicon oxide, a silicon nitride, or any combination thereof. In some implementations, layers may be deposited or stacked in alternating fashion, e.g., alternating silicon oxide and silicon nitride layers. Other examples of chemical precursors and stack materials are listed elsewhere herein.

In some implementations, a controller (e.g., 120) is part of a system, which may be part of the above-described examples, including a process chamber or another system that includes an ESC. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the processing of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of processing operations, examine a history of past processing operations, examine trends or performance metrics from a plurality of processing operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the processing and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

System and methods have now been provided that provide improved chucking or clamping capabilities over conventional systems. The above-described methods, apparatus, and systems enable a flexible usage of various clamping modes (e.g., bipolar and/or monopolar) as compared to conventional systems, and they do so while using modifications to existing technology. As a result, embodiments the improved chucking systems now include configurations involving one or more power sources.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Certain features that are described in this specification in the context of separate implementations also can be implemented in combination in a single implementation. Conversely, various features that are described in the context of a single implementation also can be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A carrier ring configured to support a semiconductor substrate, the carrier ring comprising:
a ring having an outer portion and an inner portion and defining a plane, the inner portion having an inner perimeter having a first diameter of about 298.4 to 299.5 millimeters (mm); and
a plurality of inwardly extending tabs disposed about the inner perimeter of the inner portion of the ring, the plurality of inwardly extending tabs having inner edges defining a circle having a second diameter of about 296.0 to 298.5 mm.

2. The carrier ring of claim 1, wherein:
the first diameter of the inner portion of the ring is about 299.0 mm; and
the second diameter of the plurality of inwardly extending tabs is about 297.0 mm.

3. The carrier ring of claim 1, wherein the plurality of inwardly extending tabs comprise at least 8 inwardly extending tabs.

4. The carrier ring of claim 1, wherein at least one of the plurality of inwardly extending tabs has a width of about 0.5 to 1.5 mm.

5. The carrier ring of claim 4, wherein the width of the at least one of the plurality of inwardly extending tabs is about 1.0 mm.

6. The carrier ring of claim 1, wherein at least one of the plurality of inwardly extending tabs comprises at least a portion of a top surface having an angle that is neither parallel to nor perpendicular to the plane.

7. The carrier ring of claim 6, wherein the angle of the portion of the top surface is between about 5 to 20 degrees with respect to the plane.

8. The carrier ring of claim 6, wherein the top surface of the at least one of the plurality of inwardly extending tabs comprises a minimum contact area (MCA) configured to make physical contact with the semiconductor substrate.

9. The carrier ring of claim 1, wherein the outer portion is about 0.3 to 0.7 mm thick, and the inner portion is about 0.1 to 0.5 mm thick.

10. The carrier ring of claim 1, wherein at least a portion of the plurality of inwardly extending tabs disposed about the inner perimeter of the inner portion of the ring are configured to form one or more conductive grounding points on the semiconductor substrate.

11. A carrier ring configured to support a semiconductor substrate, the carrier ring comprising:
a ring comprising an inner portion configured to support the semiconductor substrate during backside deposition on the semiconductor substrate, the ring defining a plane; and
8 to 15 inwardly extending tabs disposed about the inner portion of the ring, and configured to contact the semiconductor substrate during the backside deposition on the semiconductor substrate;
wherein at least one of the 8 to 15 inwardly extending tabs has a width of about 0.5 to 1.5 mm.

12. The carrier ring of claim 11, wherein the at least one of the 8 to 15 inwardly extending tabs comprises a top surface of having an angle of about 15 degrees or less with respect to the plane.

13. The carrier ring of claim 11, wherein the 8 to 15 inwardly extending tabs have inner edges defining a first diameter of about 296.0 to 298.5 mm; and
wherein the 8 to 15 inwardly extending tabs have outer edges attaching to the ring and defining a second diameter of about 298.4 to 299.5 mm.

14. The carrier ring of claim 11, wherein at least a portion of the 8 to 15 inwardly extending tabs are configured to allow formation of one or more conductive grounding points on the semiconductor substrate.

15. A method of depositing one or more layers on a backside of a semiconductor substrate, the method comprising:
(a) supporting the semiconductor substrate on a carrier ring, the carrier ring comprising:
a ring having an outer portion and an inner portion and defining a plane, the inner portion having an inner perimeter having a first diameter of about 298.4 to 299.5 millimeters (mm); and
a plurality of inwardly extending tabs disposed about the inner perimeter of the inner portion of the ring, the plurality of inwardly extending tabs having inner edges defining a circle having a second diameter of about 296.0 to 298.5 mm; and
(b) exposing the backside of the semiconductor substrate to process conditions that cause the one or more layers to deposit on the backside of the semiconductor substrate.

16. The method of claim 15, wherein the process conditions that cause the one or more layers to deposit comprise exposure to a chemical precursor of at least one of the one or more layers.

17. The method of claim 15, wherein at least one of the one or more layers on the backside of the semiconductor substrate comprises polysilicon, a silicon oxide, a silicon nitride, or any combination thereof.

18. The method of claim 15, wherein:
the first diameter of the inner portion of the ring is about 299.0 mm; and
the second diameter of the plurality of inwardly extending tabs is about 297.0 mm.

19. The method of claim 15, wherein the plurality of inwardly extending tabs comprise at least 8 inwardly extending tabs, at least one of the at least 8 inwardly extending tabs having a width of about 0.5 to 1.5 mm.

20. The method of claim 15, wherein at least one of the plurality of inwardly extending tabs comprises at least a portion of a top surface having an angle that is neither parallel to nor perpendicular to the plane, and the angle is about 5-20 degrees with respect to the plane.
